(19) United States
(12) Patent Application Publication
(10) Pub. No.: US 2010/0327902 A1
(43) Pub. Date: Dec. 30, 2010

(54) Power saving termination circuits for dram modules

(75) Inventor: Jeng-Jye Shau, Palo Alto, CA (US)

Correspondence Address: Bo-In Lin, 13445 Mandoli Drive, Los Altos Hils, CA, 94022, US

(73) Assignee: Uniram Technology, Inc.

(21) Appl. No.: 12/456,947

(22) Filed: Jun. 25, 2009

(51) Int. Cl. H03K 17/16; H01L 21/20

(52) U.S. Cl. 326/30; 438/381; 257/E21.09

(57) ABSTRACT

The present invention provides power saving methods by replacing termination resistors used to support SSTL DRAM interfaces with RC termination circuits; the RC termination circuits consumes significant less power relative to prior art termination resistors at low frequency and behave as a matching impedance at high frequency. Similar methods and structures are also applicable for PCIe, SATA, or MIPI differential interfaces.

### BACKGROUND OF THE INVENTION

The present invention relates generally to termination circuits used to reduce the effects of reflection at the ends of electrical wires, and more particularly to termination circuits used for “dynamic random access memory” (DRAM) interface signals.

The signal transfer rates for DRAM “stub series terminated logic” (SSTL) interfaces have been progressing exponentially. Initial generation “double data rate” (DDR) DRAM supports data transfer rates at or lower than 400 “million bits per second” (Mpbs) per signal line with clock frequencies at or lower than 200 “million cycles per second” (MHZ). The second generation DDR2 DRAM supports data transfer rate up to 800 Mbps with clock frequencies up to 400 MHZ. Current art third generation DDR3 DRAM supports 1.6 billion bits per second (Gbps) with clock frequencies up to 800 MHZ. The present invention will focus on DRAM modules with clock frequencies higher than 300 MHZ. Operating at such high frequencies, signals transferred along electrical lines on “printed circuit board” (PCB) can no longer be considered simply as discrete voltage signals, because signals transferred along the electrical lines also behave as waves traveling along transmission lines. To preserve signal integrity at high (>300 MHZ) frequencies, the effects of termination circuits placed at the end(s) of electrical lines on signal transmission must be taken into consideration.

FIGS. 1-3 are simplified illustrations of the effects of reflection on SSTL interface signals. FIG. 1(a) is a simplified symbolic diagram showing a driver (Drv) driving an electrical wire (TL) that is connected to two sensors (Ds1, Ds2) that sense signals at two different points (Qi1, Qi2) on the electrical wire (TL). In this simplified example, the end point (Qit) of the electrical wire (TL) is not connected to a termination circuit. FIG. 1(b) shows an example voltage signal that switches from a lower voltage (VL) to a higher voltage (VH), and switches back from VH to VL. At low speed, the electrical wire (TL) can be considered as a single point with uniform voltage waveform along the whole wire. The sensors (Ds1 and Ds2) will receive the ideal signal with little distortion. At high speed, the electrical wire (TL) behaves as a transmission line, and we must consider electrical signals as waves traveling along electrical wires. When the signal reaches the open end (Qit) of the electrical line, part of the wave will be reflected back to the transmission line (TL). FIG. 1(c) shows an example of the waveform detected at point Qi2 that is a combination of the original waveform in FIG. 1(b) overlapped with the reflected wave. Distortions (RFr2, RFf2) can be observed due to reflection at the terminal (Qit). The effects of reflection can be different at different points along the transmission line (TL). FIG. 1(d) shows an example of the waveform detected at point Qi1 where reflection induced distortions (RFr1, RFf1) severely distort the signal received by the sensor (Ds1).

The most common conventional method used to reduce the effect of reflection is to connect a termination resistor (RT) at the end of the electrical line (TL) as shown in FIG. 2(a). One terminal of the termination resistor (RT) is connected to the end (Qit) of the electrical wire (TL) while the other terminal of RT is connected to a voltage source (VTT). It is well known to a person of ordinary skill in the art that if the value (RL) of the termination resistor (RT) is adjusted to be similar to the “characteristic impedance” (Zo) of the electrical line (TL), reflection effects can be reduced significantly. The characteristic impedance Zo of electrical lines on a typical “printed circuit board” (PCB) is between 40 to 80 ohms, and the value (RL) of the termination resistor (RT) is typically adjusted to be within the same range. FIG. 2(b) shows an example waveform when termination resistor of proper value is properly placed. In this example, the reflection induced distortions (RFr3, RFf3) are reduced significantly by the termination resistor (RT).

The example shown in FIG. 2(a) is a single-ended signal. The same principle works for differential signals. FIG. 2(d) shows a simplified example of a pair of differential signal lines (Q+, Q−) driven by differential signal drivers (Dr+, Dr−). A termination resistor (RDT) is connected between the ends of the differential signal lines. It is well-known to a person of ordinary skill in the art that if the value of the termination resistor (RDT) is adjusted to near twice the characteristic impedance (Zo) of the differential signal lines (Q+, Q−); the reflection effects can be reduced significantly. Examples of differential signals are SSTL clock signals, the “peripheral component interconnect express” (PCIe) computer interface, the “serial advanced technology attachment” (SATA) interface for mass storage devices, and the “Mobile Industry Processor Interface” (MIPI) used in mobile devices.

In the above examples, termination resistors are represented by a simplified equivalent circuit as a single resistor (RT) connected between the end (Qit) of an electrical wire and a voltage source (VTT), as shown in FIG. 3(a). Prior art termination resistors can be implemented in a wide variety of ways. FIG. 3(b) shows a common implementation of prior art termination circuit. In this example, the end of electrical wire (Qit) is connected to two resistors (RTh, RTg); the second terminal of RTh is connected to a power supply (VDD), and the second terminal of RTg is connected to ground. The termination circuit in FIG. 3(b) is equivalent to have a termination resistance of (RTh×RTg)/(RTh+RTg) connected to a termination voltage at (RTg×VDD)/(RTh+RTg). The “termination resistor” also can be implemented using electrical elements that are not simple resistors. FIG. 3(c) illustrates an example when a transistor (MT) is used as a termination resistor. The value of effective resistance of the transistor (MT) can be adjusted by adjusting its gate voltage (VGt). Transistors are often used as on-chip termination resistors; multiple transistors may certainly be used to build equivalent circuits to function as the termination resistors.

Termination resistors are effective in reducing distortions caused by reflection, but they consume additional power. For the simplified example in FIG. 2(a), the termination resistor will sink currents between (VH−VTT)/RL and (VL−VTT)/RL, as shown in FIG. 2(c), consuming additional power relative to the no-termination circuits shown in FIG. 1(a). It is therefore desirable to provide termination circuits that can reduce reflection effects like termination resistors while consuming less power.

DRAM is one of the most common “integrated circuits” (IC) that requires termination resistors. Typical interface signals of a DDR3 DRAM chip are listed in Table 1.

TABLE 1
DDR3 DRAM interface signals

| | | | Termination |
|---|---|---|---|
| type | name | Signal type | circuits |
| addresses | A14-A0, BA2-BA0. | SSTL | On PCB |
| Control | CAS, RAS, WE, CS, CKE, | SSTL | On PCB |
| | ODT. | | |
| clocks | CK, CK# | differential | On PCB |
| data | DQS, DQS#, TDQS, TDQS#, | SSTL | On chip |
| | DQ7-DQ0 | | |

In our terminology, DRAM interface signals include address signals, control signals, clock signals, and data signals. “DRAM address signals” include address signals (A14-A0) and bank address signals (BA2-BA0) used by standard DRAM chips. “DRAM control signals” including the “column address strobe” (CAS), “row address strobe” (RAS), “write enable” (WE), “chip select (CS), “clock enable” (CKE), and “on-chip termination enable” (ODT) signals used by standard DRAM chips. “DRAM clock signals” include the clock (CK) and inverted clock (CK#) signals used by DRAM chips. “DRAM data signals” include data signals (DQ7-DQ0), data strobe (DQS, TDQS) and inverted data strobe (DQS#, TDQS#) signals used by DRAM chips. These DRAM interface signals are well known to the art; the exact names used by different parties may differ slightly, but the meanings of DRAM interface signals are well defined. DRAM chips are typically placed on a “printed circuit board” (PCB) called “dual in line memory module” (DIMM). FIG. 4(a) is a simplified schematic diagram illustrating the electrical connections of a DDR3 DRAM module. A DRAM DIMM typically has 4 to 36 DRAM chips. 8 DRAM chips (DRAM1-DRAM8) are shown in our examples. Each DRAM chip typically has 4, 8, or 16 data signals (DQ) plus 2 or 4 data strobe (DQS, DQS#, TDQS, TDQS#) signals. For simplicity, we only draw four data lines in each DRAM chip to represent all data and data strobe signals of the DRAM chip. As shown in FIG. 4(a), the end of each data line is connected to a termination resistor (401) inside DRAM. In our examples, a simplified symbolic view of a single resistor is used to represent the prior art termination resistors, while the actual termination resistors can be more complex. On a DRAM module, address and control (A&C) lines are typically shared by multiple DRAM chips, and connected to termination resistors (402) at the end of each wire. For simplicity, we only use 8 lines to represent all address and control signals (A&C) in our examples. For the example shown in FIG. 4(a), all 8 DRAM chips (DRAM1-DRAM8) share one set of address and control (A&C) signals. A DRAM module can have more sets of address and control signals. For example, registered DIMM (RDIMM) can have 2 or 4 sets of A&C signals in each module; that means 2 or 4 sets of termination resistors are needed. In FIG. 4(a), all 8 DRAM's share a pair of differential clock (CK, CK#) signals that are connected to a termination resistor (404). DRAM modules often have more than one pair of clock lines while each pair requires one termination resistor.

FIG. 4(b) shows a simplified symbolic view of the structures of a typical DDR3 DRAM DIMM. In this example, 8 DRAM chips (DRAM1-DRAM8) are placed on a printed circuit board (411). Gold fingers (412) at one edge of the PCB (411) provide the connections to computer interface signals. Termination resistors (414-417) for address and control signals are typically placed near the edge of the PCB. There are designs that place the termination resistors near the center of the PCB in physical locations, but those termination resistors are still connected near the ends of electrical connections. The termination resistors for data signals are typically inside of DRAM chips that are not visible without opening the chips.

The initial generation DDR DRAM modules did not use any on-board termination resistors. Multiple DDR DRAM modules shared the same termination resistors with chipsets so that the power consumed by termination resistors was not significant. For DDR2 DRAM, each DRAM chip had on-chip termination resistors for all data and data strobe signals. Typically no termination resistors were used for address and control signals on DDR2 modules. Current art DDR3 DRAM not only has on-chip termination resistors for all data and data strobe signals, but also has one or more sets of on-PCB termination resistors for address and control signals. We can see the trend that more and more termination resistors are used for newer generations of DRAM modules; these termination resistors start to consume significant power.

DRAM is one of the most widely used IC. Each year billions of DRAM chips are manufactured connected to termination resistors that continuously burn power. It is therefore highly desirable to provide power saving solutions for termination circuits used for DRAM modules and other popular interfaces such as PCIe, SATA, or MIPI interfaces.

### SUMMARY OF THE INVENTION

The primary objective of this invention is, therefore, to reduce the power consumed by termination circuits for DRAM modules. Another objective is to provide power saving termination circuits for PCIe, SATA, or MIPI interfaces. These and other objectives are achieved by using capacitor(s) connected in series with resistor(s) as termination circuits. The resulting termination circuits are capable of reducing reflection effects while consuming much less power than prior art termination resistors.

While the novel features of the invention are set forth with particularly in the appended claims, the invention, both as to organization and content, will be better understood and appreciated, along with other objects and features thereof, from the following detailed descriptions taken in conjunction with the drawings.

### BRIEF DESCRIPTION OF THE DRAWINGS

FIGS. 1(a-d) are simplified examples of a conventional interface circuit without termination circuit;

FIGS. 2(a-d) illustrate the structures and operation principles of conventional termination resistors;

FIGS. 3(a-c) show examples of conventional termination resistors;

FIGS. 4(a,b) illustrate the electrical connections and the structures of conventional DRAM DIMM using termination resistors;

FIGS. 5(a-d) provide simplified examples that illustrate the structures and operation principles of RC termination circuits;

FIGS. 6(a-d) provide simplified examples for RC termination circuits;

FIGS. 7(a-j) show examples of various configurations for RC termination circuits;

FIG. 7(k) shows example methods to adjust the resistor and/or capacitor values for RC termination circuits;

FIGS. 8(a,b) illustrate example electrical connections and the structures of a DRAM DIMM using RC termination circuits;

FIGS. 9(a-e) show various example methods and structures to build RC termination circuits of the present invention;

FIGS. 10(a-d) show various example methods and structures to build embedded RC termination circuits of the present invention;

FIGS. 11(a-e) are cross section diagrams illustrating example screen printing manufacture processes for RC termination circuits of the present invention; and

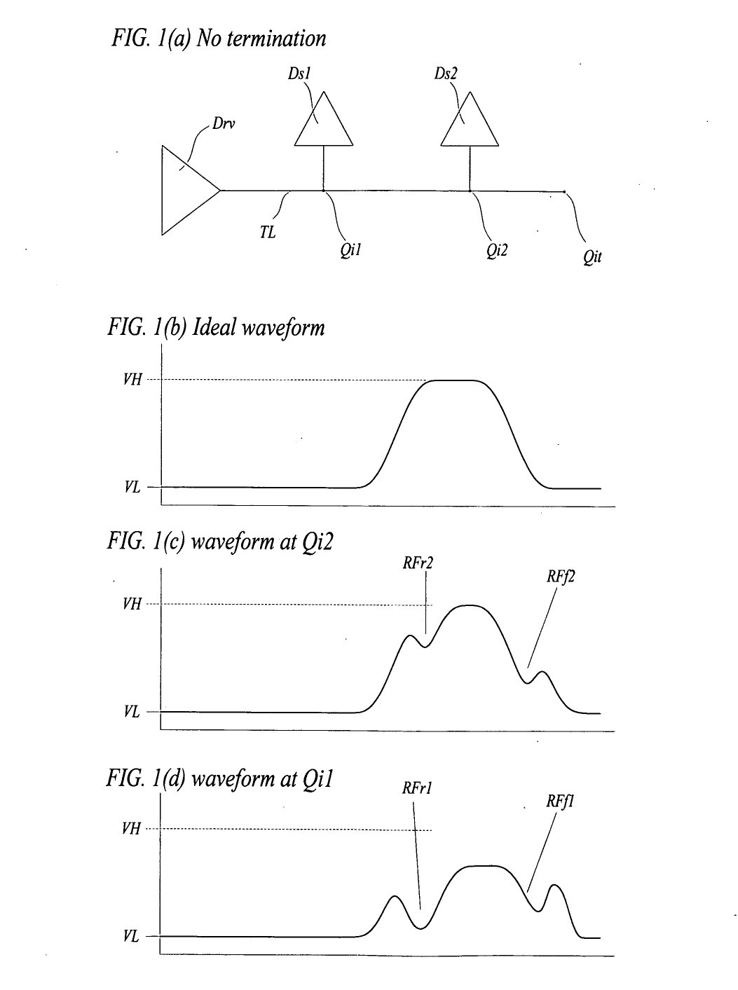

12(a-e) are cross section diagrams illustrating another example screen printing manufacture process for RC termination circuits of the present invention.

### DETAILED DESCRIPTION OF THE INVENTION

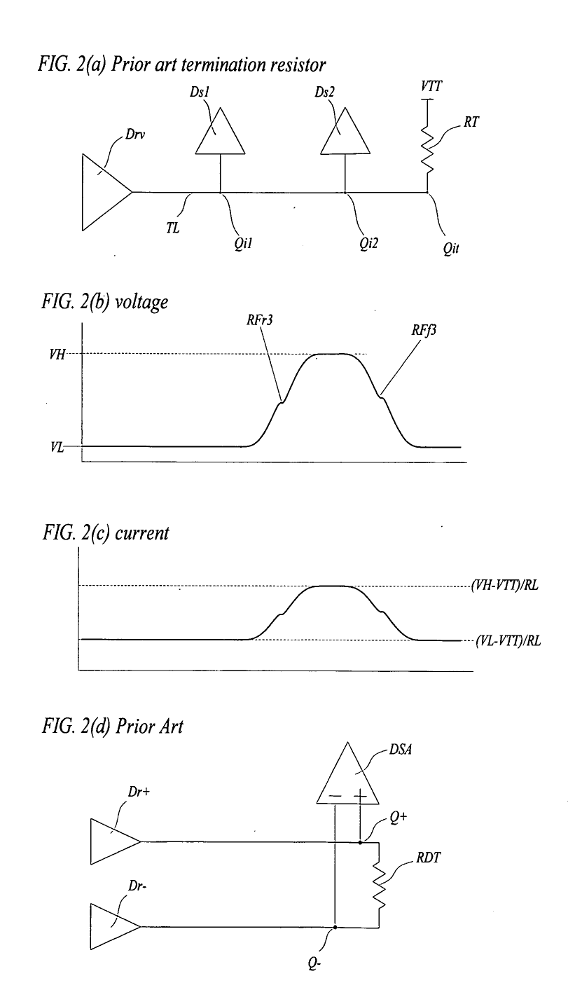

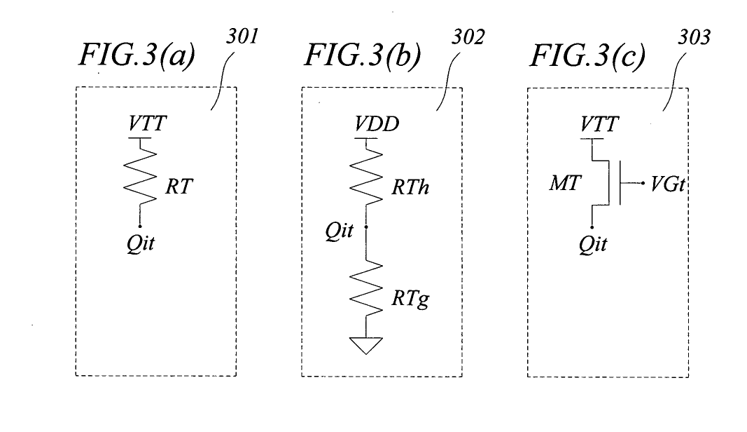

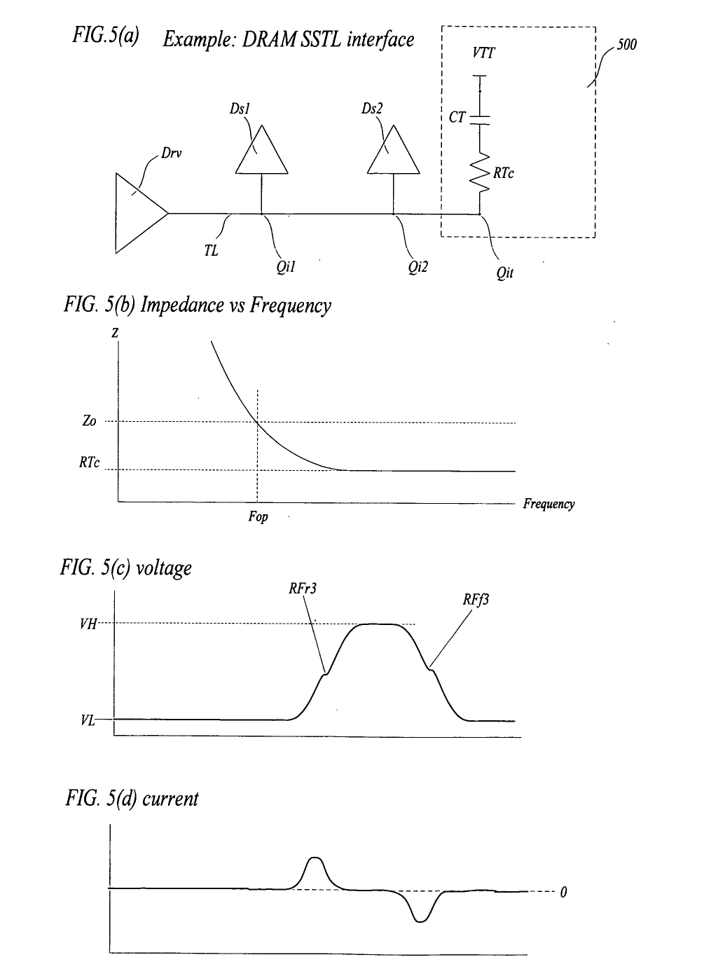

FIGS. 5(a-d) are simplified symbolic diagrams illustrating the operation principles of RC termination circuits. FIG. 5(a) shows a driver (Drv) driving an electrical wire (TL) that is connected to two sensors (Ds1, Ds2) at two different points (Qi1, Qi2). The end point (Qit) of the electrical wire (TL) is connected to a resistor (RTc) that is connected in series with a capacitor (CT) while connecting to a voltage source (VTT). The voltage of this voltage source (VTT) can be the same as the termination voltage of prior art termination resistors; it also can be a different voltage. We will call these types of termination circuits that comprise at least one capacitor and one resistor connected in series as “RC termination circuits”. The RC termination circuits are less sensitive to the voltage values of voltage sources than prior art termination resistors. This circuit shown in FIG. 5(a) is nearly identical to the circuit in FIG. 2(a) except that the termination resistor (RT) in FIG. 2(a) is replaced with an RC termination circuit (500). The impedance of the RC termination circuit (500) as a function of frequency is shown in FIG. 5(b). At low frequency, the total impedance is very high due to the capacitor (CT); the RC termination circuit (500) consumes little power at low frequency. The impedance of the capacitor (CT) decreases as frequency increases so that the impedance of the RC termination circuit (500) approaches the resistance of the resistor (RTc) at high frequency. We can adjust the values of the capacitor (CT) and the resistor (RTc) so that the total impedance of the termination circuit (500) is close to the characteristic impedance (Zo) of the electrical line (TL) near the operation frequency (Fop) of an interface. DRAM SSTL interfaces have well-controlled driver specification, so the RC termination circuits (500) can be adjusted to perform nearly as well as prior art termination resistors. FIG. 5(c) shows an example of the signal detected by one of the sensor (Ds2). The distortion (RFr3, RFf3) introduced by reflection is reduced significantly by the RC termination circuit (500).

The disadvantage of the termination circuit (500) in FIG. 5(a) is that it is effective in reducing reflection effects only in relatively narrow frequency ranges; while a prior art termination resistor is effective in wide frequency ranges. The characteristic frequencies of a signal also can be very complex; it is related strongly to the rising and falling time of the signal drivers. The advantage of the termination circuit (500) is power saving. FIG. 5(d) is a simplified diagram showing the current flowing through the RC termination circuit (500) while the voltage on the electrical line (TL) is the waveform shown in FIG. 5(c). Because of the serial capacitor (CT), current flows through the termination circuit (500) only when the voltage is switching, as shown in FIG. 5(d). Prior art termination resistors consume power all the time, even when the voltage is not switching, as shown in FIG. 2(c). Therefore, RC termination circuits consume significantly less power relative to prior art termination resistors.

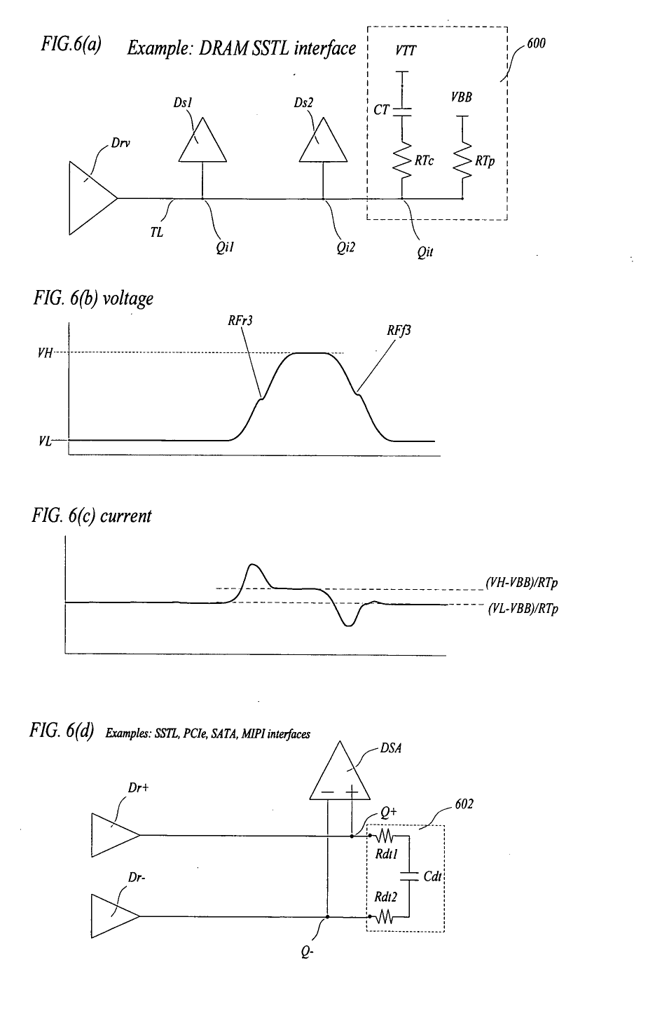

One of the problems of the termination circuit (500) shown in FIG. 5(a) happens when the driver (Drv) is set at a high impedance state for a long time; the voltage on the electrical line (TL) may drift to an undesired level under such condition. A simple solution is to add a resistor (RTp) between the end point (Qit) and a bias voltage (VBB), as shown in FIG. 6(a). The bias voltage (VBB) can be the same as VTT or a different voltage. Typically, the VBB voltage level is adjusted between VH and VL. This parallel resistor (RTp) causes leakage currents even when the voltage is not switching, as illustrated in FIG. 6(c), so that the power saving of the RC termination circuit (600) in FIG. 6(a) is not as effective as the RC termination circuit (500) in FIG. 5(a). However, the difference can be small if the value of the bias resistor (RTp) is much higher than the value of RTc.

The above examples are single-ended interface signals. The same principle works for differential signals. FIG. 6(d) shows a simplified example of a pair of differential signal lines (Q+, Q−) driven by differential signal drivers (Dr+, Dr−). A termination circuit (602) that comprises serial resistors (Rdt1, Rdt2) and capacitor (Cdt) is connected between the ends of the differential signal lines. If the equivalent impedance of the termination circuit (602) at operation frequency range is adjusted to be near twice that of the characteristic impedance (Zo) of the differential signal lines (Q+, Q−), the reflection effects can be reduced significantly while consuming lower power than the prior art termination circuit shown in FIG. 2(d).

For an electrical line terminated with an RC termination circuit, when the voltage on the electrical line is not switching, the termination circuit consumes little power. When the voltage is switching near a predefined range of operation frequencies, the RC termination circuit behaves as a matching impedance to reduce reflection effects. The basic structures shown in the above example comprises a capacitor (or an equivalent circuit of a capacitor) connected in series with a resistor (or an equivalent circuit of a resistor). A circuit designer can use many kinds of equivalent circuits to build the RC termination circuits in different configurations. We will discuss a few more example embodiments in the following sections. The scope of the present invention should not be limited by the example configurations of RC termination circuits.

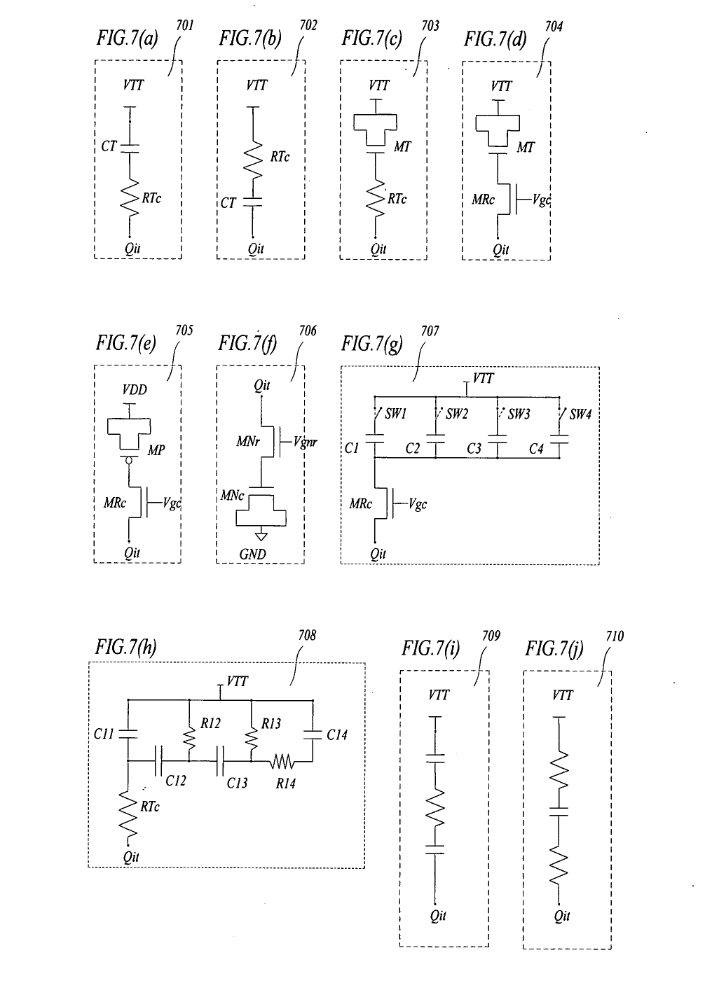

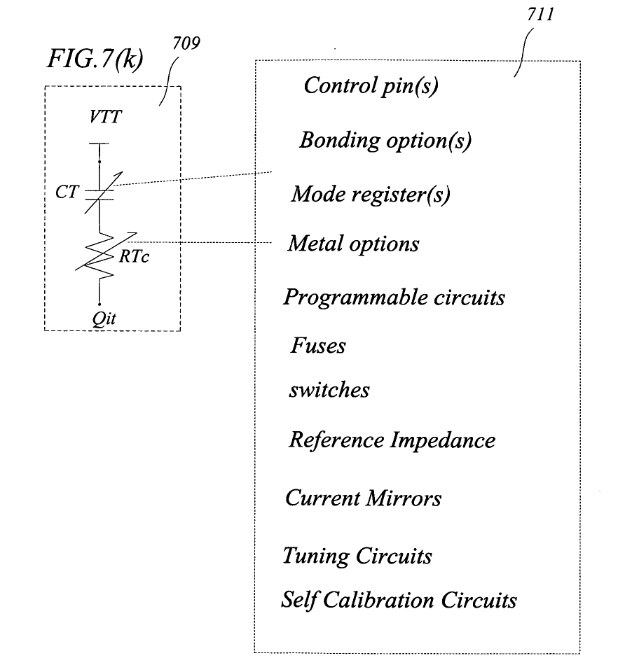

FIG. 7(a) shows simplified symbolic views for one example RC termination circuit. This RC termination circuit (701) comprises a resistor or an equivalent circuit of a resistor (RTc) that is connected to the end (Qit) of an electrical wire, and a capacitor or an equivalent circuit of a capacitor (CT) that is connected to the resistor (RTc) and a voltage source (VTT). We can exchange the positions of capacitors and resistors as shown in FIG. 7(b) to serve the same function. The termination circuit in FIG. 7(b) comprises a capacitor or the equivalent circuit of a capacitor (CT) connected to the end (Qit) of electrical wire, and a resistor or the equivalent circuit of a resistor (RTc) that is connected to the capacitor (CT) and a voltage source (VTT). FIG. 7(c) shows an embodiment of an RC termination circuit (703) that uses a transistor (MT) as a capacitor. The gate of the transistor (MT) is connected to the resistor (RTc) while the source and drain of the transistor are connected to VTT. FIG. 7(d) shows another embodiment of an RC termination circuit (704) that uses a transistor (MT) as a capacitor, and uses another transistor (MRc) as a resistor. The gate of the first transistor (MT) is connected to the source of the second transistor (MRc) while the source and drain of the first transistor are connected to VTT. The drain of the second transistor (MRc) in FIG. 7(d) is connected to the end (Qit) of the electrical line. We can adjust the equivalent resistance by adjusting the gate voltage (Vgc) of the transistor (MRc). FIG. 7(e) shows another embodiment of an RC termination circuit (705) where a p-channel transistor (MP) is used as a capacitor; the source and drain of the transistor (MP) are connected to power supply voltage (VDD). The termination circuits (703, 704, 705) shown in FIGS. 7(c, d, e) all support the same equivalent circuit as the termination circuit (701) in FIG. 7(a). FIG. 7(f) shows a termination circuit (706) that uses two transistors (MNr, MNc) configured as an equivalent circuit of the termination circuit in FIG. 7(b). The gate voltage (Vgnr) of MNr can be adjusted to control the equivalent resistance value. The source and drain of transistor MNc are connected to ground in this example. FIG. 7(g) shows another embodiment of an RC termination circuit (707) with adjustable capacitance and resistance values. The capacitance can be adjusted by controlling the state of switches (SW1-SW4) connected between VTT and capacitors (C1-C4). The resistance can be adjusted by controlling the gate voltage (Vgc) of the transistor (MRc). FIG. 7(h) shows an alternate embodiment of a termination circuit (708) comprising multiple capacitors (C11, C12, C13, C14) and resistors (RTc, R12, R13, R14); such R-C networks can be designed to support wider frequency ranges. FIG. 7(i) shows another embodiment where two capacitors and one resistor are connected in series to form an RC termination circuit. FIG. 7(j) shows another alternate embodiment where two resistors and one capacitor are connected in series to form an RC termination circuit.

RC termination circuits function within a range of frequencies or signal switching rates. Operations in different ranges of frequencies (or switching rates) often require an adjustment of the capacitance and/or resistance values. It is therefore good practice to use variable capacitors and/or variable resistors as the components of the RC termination circuits. FIG. 7(k) lists examples for the methods that can be used to adjust the capacitance/resistance values. For example, we can use control pin(s), bonding option(s), mode register(s), programmable circuits, metal options, fuses, or switches as programmable parameters for controlling the capacitance/resistance values. A reference impedance, such as a reference resistor, working with impedance matching circuits such as current mirrors, can allow accurate tuning. It is also desirable to have self-tuning circuits that adjust the capacitance/resistance values automatically. In the following discussions and in the figures, for simplicity and clarity, we will use the symbolic view of one resistor connected in series with one capacitor to represent a set of RC termination circuit while the actual implementation can be much more complex, such as the examples shown in FIGS. 7(a-i) or in FIG. 6(a). It is to be understood that the scope of the invention is not limited by the specific embodiments of the RC termination circuits.

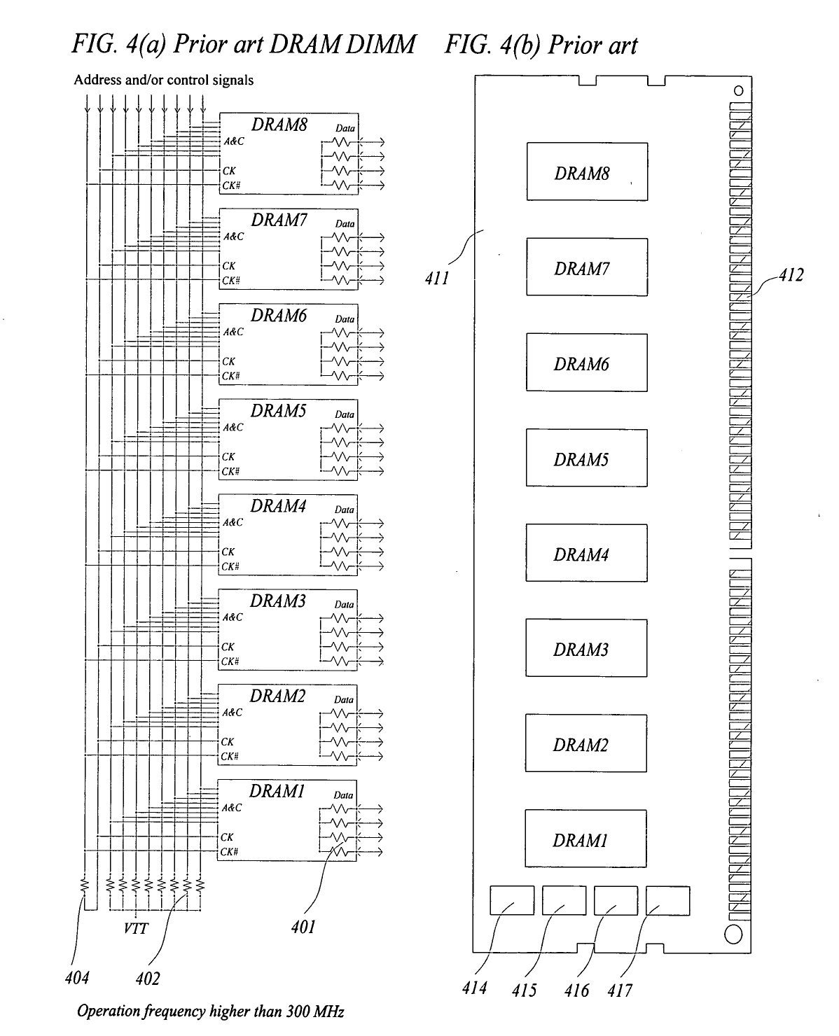

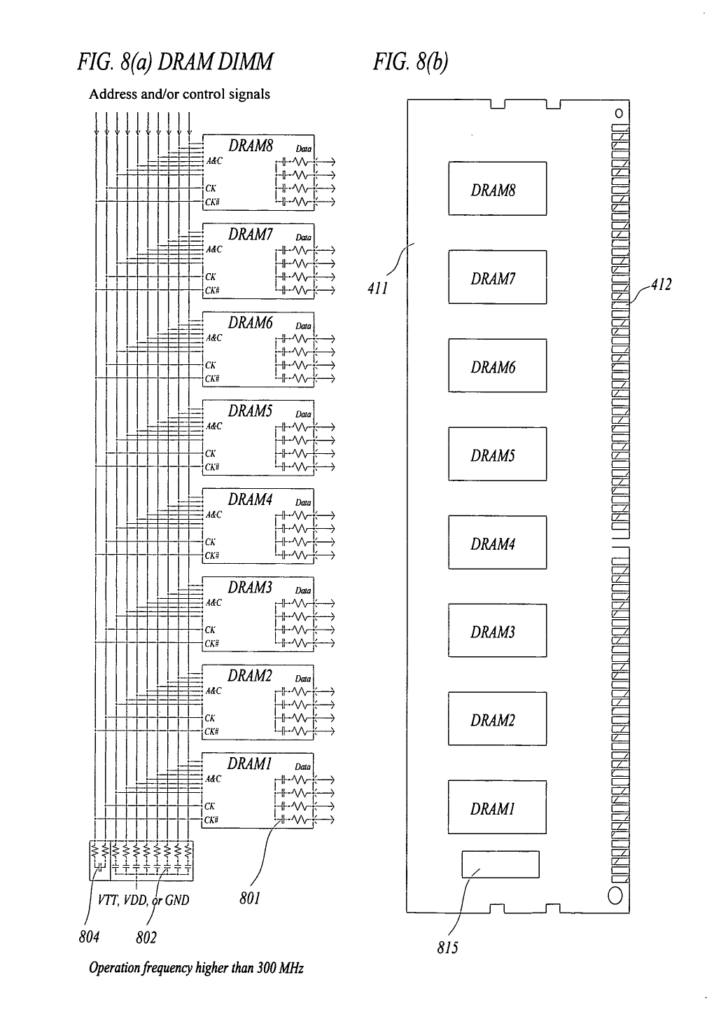

FIGS. 8(a, b) show an example when RC termination circuits are used for DRAM modules. FIG. 8(a) is a simplified schematic diagram illustrating the electrical connections of a DDR3 DRAM DIMM module. This example is similar to the prior art example shown in FIG. 4(a) except that the termination resistors (401, 402, 404) in FIG. 4(a) are replaced by RC termination circuits (801, 802, 804). FIG. 8(b) shows a simplified symbolic view of the structures of the DRAM module. In this example, 8 DRAM chips (DRAM1-DRAM8) are placed on a printed circuit board (411). In this example, the RC termination circuits for address and control signals are integrated into a single component (815) for space-saving purposes. The termination circuits for data signals are typically inside of DRAM chips that are not visible without opening the chips.

In FIG. 8(a), each RC termination circuit is shown as a simplified symbolic view of one resistor and one capacitor, while it is clearly understood that other types of RC termination circuits may be flexibly implemented. In this embodiment, RC termination circuits are used for all DRAM interface signal lines. It is certainly a design option to use RC termination on a subset of DRAM interface signal lines.

While specific embodiments of the invention have been illustrated and described herein, it is realized that other modifications and changes will occur to those skilled in the art. The basic components of the RC termination circuits are capacitors and resistors. These components can be manufactured in wide varieties of methods and connected in different ways. It is to be understood that there are many other possible modifications and implementations so that the scope of the invention is not limited by the specific embodiments discussed herein.

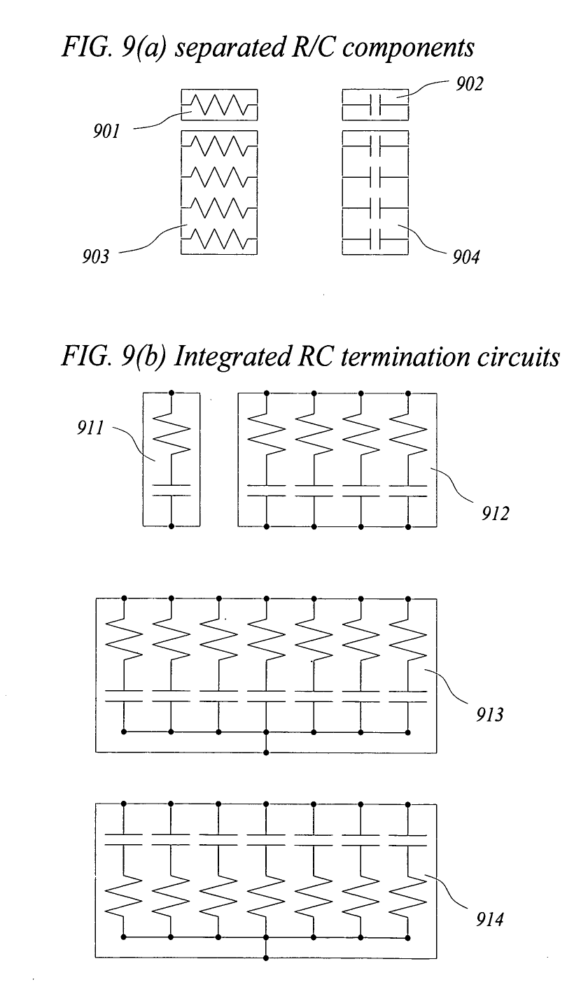

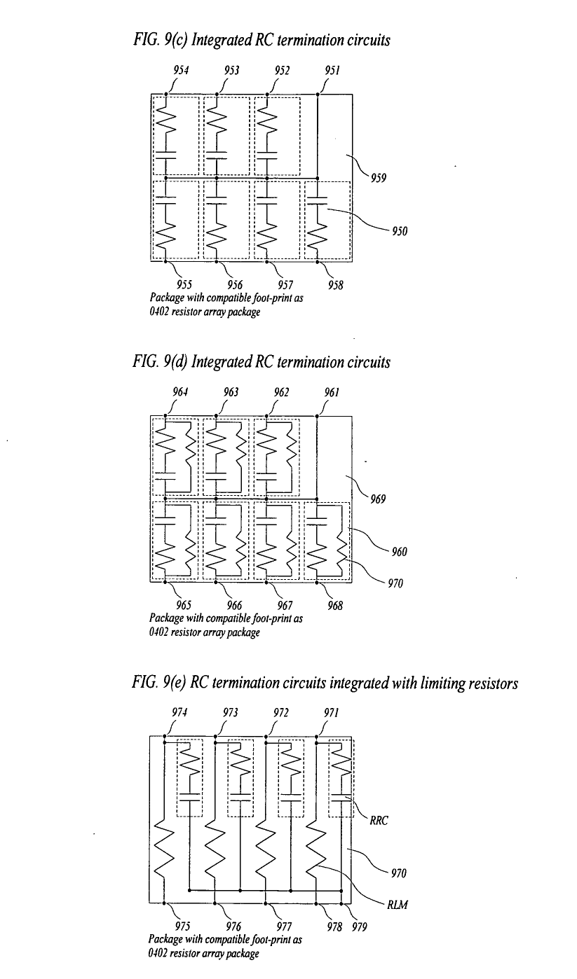

FIGS. 9(a-e) show examples of RC termination circuits arranged in different configurations. For simplicity, we will represent a package symbolically by a rectangle box enclosing circuit components. Pins on the package will be represented symbolically by a circular dot at the edge of the rectangle box. To build RC termination circuits, we can use separated resistor (901) components and capacitor (902) components shown in FIG. 9(a) as building blocks to build RC termination circuits. Separated resistors and capacitors are readily available, but separated components occupy more space and cost more. One method to reduce space/cost is to integrate multiple resistors (903) into one packaged component or integrate multiple capacitors (904) into one packaged component, as illustrated symbolically in FIG. 9(a).

For cost/space saving, it is highly desirable to integrate both capacitors and resistors into the same packaged component. FIG. 9(b) shows symbolically a resistor and a capacitor integrated into one packaged component (911). It is even more desirable to integrate multiple sets of RC termination circuits into one packaged component (912) as illustrated symbolically in FIG. 9(b). To reduce pin count, multiple sets of RC termination circuits can share one terminal. For example, an integrated component (913) can share capacitor terminals. For another example, an integrated component (914) can share resistor terminals. It is highly desirable to integrate multiple RC termination circuits into packages with compatible foot prints to serve as 0402 packages commonly used for current art resistor arrays. FIG. 9(c) shows the symbolic structures of an 8-pin component (959) that integrates seven RC termination circuits (950) into one package. One terminal of the RC termination circuits is connected to one pin (951) while the other terminals of RC termination circuits are connected separately to other pins (952-958). This device (959) can be packaged with compatible foot prints as prior art 0402 resistor arrays that are currently the most common components used for prior art termination resistors on DDR3 DRAM modules. FIG. 9(d) shows the symbolic structures of another 8-pincomponent (969) that integrates seven RC termination circuits (960) into one component. This termination circuit (960) has one additional bias resistor (970) as illustrated in FIGS. 6(a-d). One terminal of the RC termination circuits is connected to one pin (961) while the other terminals of RC termination circuits are connected separately to other pins (962-968). This device (969) also can be packaged with compatible foot prints as prior art 0402 resistor arrays. FIGS. 9(c,d) show examples of integrated RC termination circuits with particular configurations and particular pin counts. We certainly can build integrated RC termination circuits with different pin counts and in different configurations. In many cases, it is desirable to integrate additional circuit components into the same package as RC termination circuits. FIG. 9(e) shows an example when limiting resistors (RLM) are integrated into the same package as RC termination circuits (RRC). Limiting resistors are typically placed along the data paths on a DRAM module. Typical values of DRAM limiting resistors are 20 to 25 Ohms. FIG. 9(e) shows the symbolic structures of a component (970) that integrates four RC termination circuits (RRC) and four limiting resistors (RLM) into one component. One terminal of the RC termination circuits is connected to one pin (979) while the other terminals of RC termination circuits are connected separately to other pins (971-974); one terminal of the limiting resistors (RLM) is connected to the pins (971-974) that are also connected to RC termination circuits, while the other terminal of the limiting resistors is connected to separated pins (975-978) as shown in FIG. 9(e). This device (970) also can be packaged with similar foot prints as prior art 0402 or 0603 resistor arrays. It is designed to support the functions of limiting resistors as well as termination circuits for DRAM data signals.

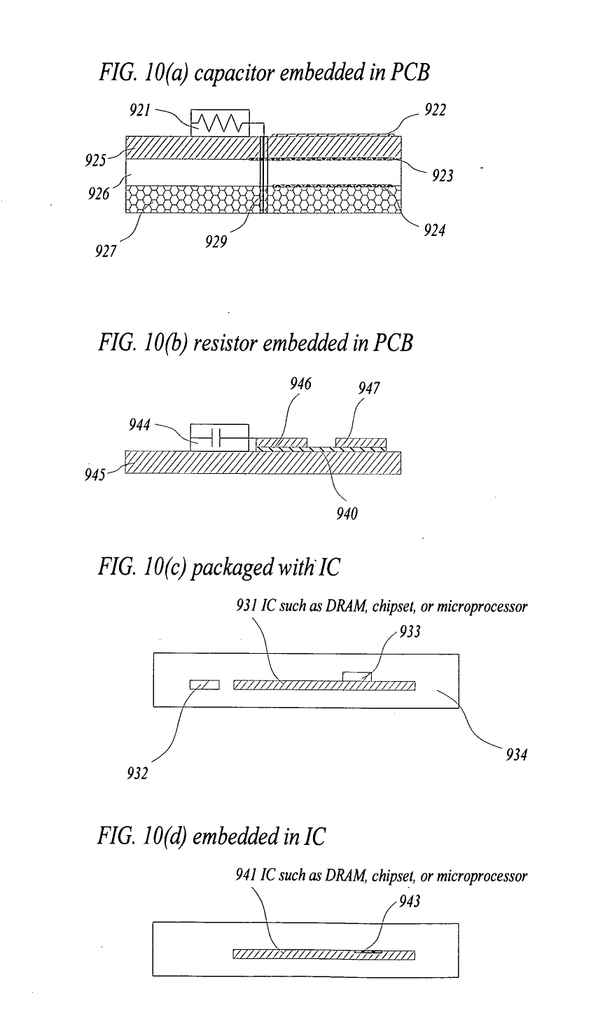

Besides using circuit components, it is desirable to use structures already available in printed circuit boards to build embedded components for the termination circuits of the present invention. FIG. 10(a) shows the cross-section views of an example when PCB embedded capacitor is used as a component for a termination circuit of the present invention. In this example, a resistor (921) is connected through a via (929) to a metal plate (923) embedded in PCB (927). This metal plate (923) is placed between one top metal plate (922) and one bottom metal plate that are separated by insulator layers (925, 926). The top and lower metal plates (922, 924) are connected to voltage source(s) (not shown). These metal plates (923, 922, 924) form an embedded capacitor to serve as a component of an RC termination circuit. This example illustrates a capacitor formed between three metal plates. We certainly can use a different number of metal plates to achieve the same purpose. FIG. 10(b) shows the cross-section views of an example when a PCB embedded resistor is used as a component for a termination circuit of the present invention. PCB embedded resistors have been developed in recent years. In this example, a capacitor (944) is connected through a metal line (946) to a PCB embedded resistor layer (940) embedded in PCB (945). The other end of the embedded resistor (940) is connected to another metal line (947). The resistance value of the embedded resistor (940) is determined by the geometry of the structures. The capacitor (944) can be a discrete capacitor component or a PCB embedded capacitor.

Another space saving solution is to place RC termination circuits into IC chips such as DRAM, chipset, or microprocessor chips. FIG. 10(c) shows symbolic cross-section views for an example when integrated RC termination circuits (933) are manufactured into a component that can be placed on top of an IC (such as DRAM, chipset, or microprocessors), and integrated into the same package (934) using well-known stacked-chip packaging technologies. It is also possible to place termination circuits (932) to the side of the IC (931) and packaged together with the IC using well-known “multiple chip module” (MCM) or “system in package” (SIP) technologies.

Another space saving solution is to build RC termination circuits (943) as part of an IC (941) as illustrated symbolically in FIG. 10(d). Current art DRAM IC already have prior art termination resistors (typically implemented by transistors) embedded in IC for data signals. Embedded RC termination circuits can be implemented by connecting on-chip capacitors (typically implemented by transistors) to the resistors. It is also possible to add embedded RC termination circuits to the address and control signals (refer to Table 1) inside a DRAM chip. Since termination circuits for address and control signals are typically shared by multiple DRAM chips, it is desirable to add a signal to the DRAM interface that can disable or enable those embedded termination circuits of the present invention.

While specific embodiments of the invention have been illustrated and described herein, it is realized that other modifications and changes will occur to those skilled in the art. The capacitors and resistors can be manufactured in wide varieties of methods. It is to be understood that there are many other possible modifications and implementations so the scope of the invention is not limited by the specific embodiments discussed herein.

Prior art resistor arrays are often manufactured by screen printing technologies. Screen printing is a printing technique that uses a woven mesh to support an ink-blocking stencil. The attached stencil forms open areas of mesh that transfer ink as a sharp-edged image onto a substrate. When screen printing technologies are used to manufacture electrical circuit components, materials with different electrical properties (conductors, insulators, resistors) are mixed with solutions as ink and patterned onto a substrate by screen printing. In the art of electrical designs, screen printing technologies are often called “thick film technologies”, in contract to “thin film technologies”. That is because the thicknesses of screen printing layers are typically measured in tens of micrometers while the thicknesses of “thin films” commonly used in integrated circuits are typically thinner than 2 micrometers. The costs of screen printing technologies are typically lower than printed circuit board technologies or integrated circuit technologies.

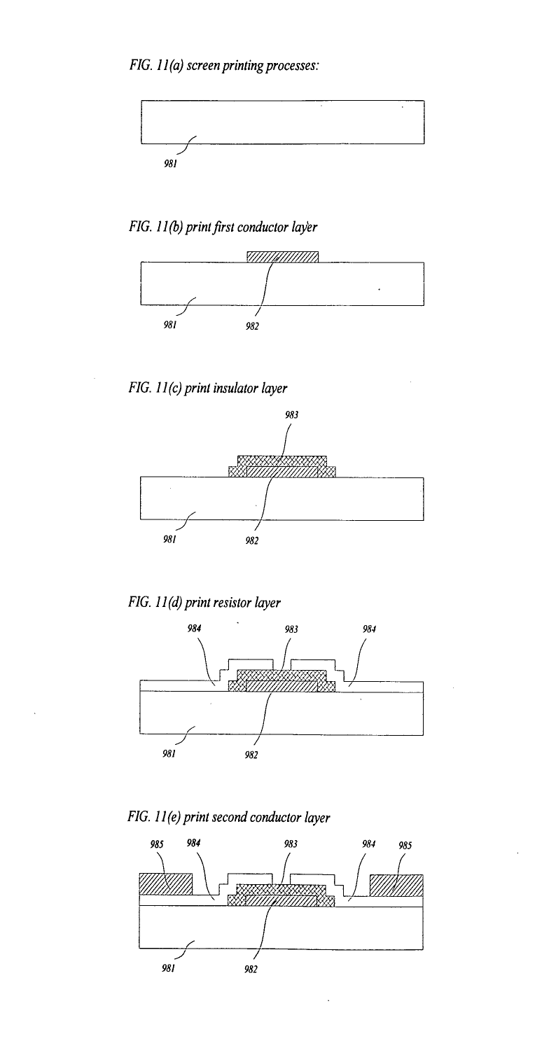

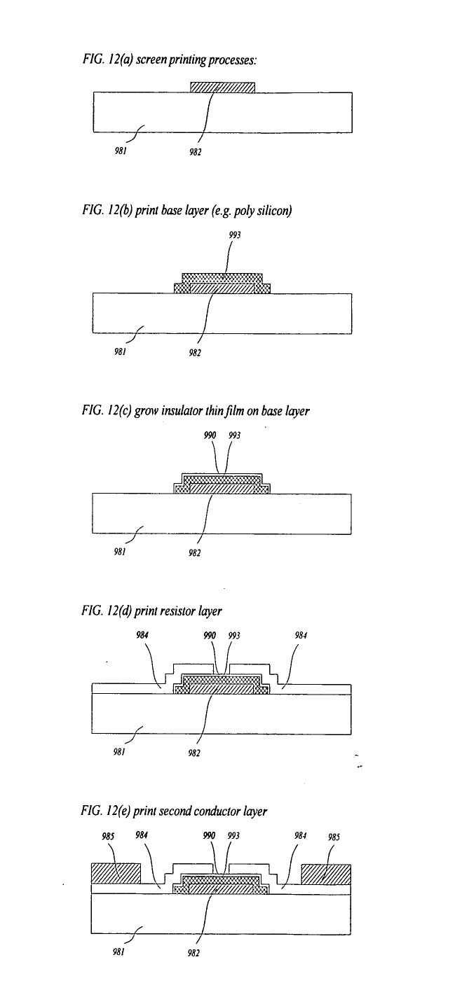

The DRAM market is a price sensitive market. It is therefore highly desirable to manufacture the RC termination circuits of the present invention using low cost screen printing technologies. FIGS. 11(a-e) are cross section diagrams illustrating example processes for manufacturing RC termination circuits by screen printing. The starting material is a substrate (981), as illustrated in FIG. 11(a). The substrate for this application is typically ceramic material, but other types of materials, such as metal plates, are also applicable in various designs. The first step of this example screen printing manufacture process is to print a conductor layer (982) on the substrate (981) as shown in FIG. 11(b). Silver is commonly used as a screen printing conductor material, but other conductor materials are also available. An insulator layer (983) is printed on top of the conductor layer (982) as illustrated in FIG. 11(c). The following processes are similar to screen printing processes of resistor arrays. Typically, a resistor layer (984) is printed on top of the layers, as shown in FIG. 11(d). The materials used for resistor layers are well known to the art of screen printing. The resistor layer (984), the insulator layer (983), and the first conductor layer (982) form capacitors between them. The values of the capacitors are determined by the overlapped areas between the three layers (982-984) and the thickness (plus the dielectric constant) of the insulator layer (983). Another layer of conductor (985) is printed on the resistor layer (981) as illustrated in FIG. 11(e). The values of resistors are determined by the geometry of the resistor layer (981). The structures shown in FIG. 12(e) provide the components needed to support RC termination circuits of the present invention; the remaining processes are similar to the manufacture of resistor arrays.

While specific embodiments of the invention have been illustrated and described herein, it is realized that other modifications and changes will occur to those skilled in the art. FIGS. 11(a-e) are simplified symbolic views of screen printing processes. For simplicity, the dimensions are not drawn to scale. We also did not discuss details that are well known to the art of screen printing, such as the heat treatments between each layer printing. It is to be understood that there are many other possible modifications and implementations so the scope of the invention is not limited by the specific embodiments discussed herein.

In the above example, an insulator layer (983) deposited by screen printing is used as the insulator material for capacitors. Such insulator layer deposited by screen printing is typically measured in tens of micrometers. It is desirable to use thin film insulators that is thinner than 2 micrometers to build capacitors in order to reduce the size of the RC termination circuits. FIGS. 12(a-e) are cross section diagrams illustrating manufacture processes combining screen printing and thin film technologies to build RC termination circuits of the present invention. The steps for printing the first conductor layer (982) on a substrate (981) are similar to the steps in FIGS. 11(a, b), as illustrated by the cross section diagram in FIG. 12(a). The next step is to print a base layer (993), instead of an insulator layer, on top of the conductor layer (982) as illustrated in FIG. 12(b). This base layer (993) comprises materials that are conductive, while allowing growth of thin film insulator on its surface. A typical choice of this base layer (993) is polycrystalline silicon. The next step is to grow a thin film insulator layer (990) on the surface of the base layer (993). The most well known method is to grow oxide or nitride thin film layers on polycrystalline silicon. The manufacture processes to grow oxide or nitride thin film on the surface of polycrystalline silicon are well known to the art so that there is no need for further descriptions. After growing the insulator thin film, the following steps are similar to the examples in FIGS. 11(d,e). A resistor layer (984) is printed as illustrated in FIG. 12(d), and the second layer conductor (985) is printed as illustrated in FIG. 12(e). Thin film insulator (990) grown on the base layer (993) is typically much thinner than screen printing insulator layers so we can reduce the dimension of RC termination circuits.

While specific embodiments of the invention have been illustrated and described herein, it is realized that other modifications and changes will occur to those skilled in the art. In the above example, thin film insulator layer is grown on the surface of a base layer deposited by screen printing. We certainly can use other thin film manufacturing technologies, such as chemical vapor deposition (CVD) or sputtering technologies, to deposit the insulator thin film. It is to be understood that there are many other possible modifications and implementations so the scope of the invention is not limited by the specific embodiments discussed herein.

In this patent application, “screen printing” is a printing technique that uses a woven mesh to support an ink-blocking stencil. The attached stencil forms open areas of mesh that transfer ink as a sharp-edged image onto a substrate. When screen printing technologies are used to manufacture electrical circuit components, materials with different electrical properties (conductors, insulators, resistors) are mixed with solutions to be prepared as ink and patterned onto a substrate by screen printing. In the art of electrical designs, screen printing technologies are often called “thick film technologies”, in contrast to “thin film technologies”. In our definition, a “thin film” is defined as a layer of materials with thicknesses thinner than 2 micrometers.

In this patent application, “DRAM interface signals” are defined as the electrical signals external to DRAM chips that are needed to support DRAM operations. We further divide DRAM interface signals into subgroups including (but not limited to) address signals, control signals, clock signals, and data signals. “DRAM address signals” include address signals (A) and bank address signals (BA) used by DRAM chips. “DRAM control signals” include the “column address strobe” (CAS), “row address strobe” (RAS), “write enable” (WE), “chip select (CS), “clock enable” (CKE), and “on-chip termination enable” (ODT) signals used by DRAM chips. “DRAM clock signals” include the clock (CK) and inverted clock (CK#) signals used by DRAM chips. “DRAM data signals” include data signals (DQ), data mask (DM), data strobe (DQS, TDQS) and inverted data strobe (DQS#, TDQS#) signals used by DRAM chips. These DRAM interface signals are well known to the art; the exact names may differ slightly, but the meanings of DRAM interface signals are well defined. The present invention uses RC termination circuits, instead of prior art termination resistors, to support a plurality of DRAM interface signals for power saving purposes. It is not necessary to place RC termination circuits on all DRAM interface signals; partial replacement maybe desirable in many cases. For example, we may use RC termination circuits on address signals and part of control signals, while still using prior art termination resistors for clock and data signals. The “DRAM interface signal lines” defined in this patent application are board level signal lines supporting DRAM interface signals (defined above) on DRAM dual in-line memory modules (DIMM). A DIMM, or dual in-line memory module, comprises a series of dynamic random access memory integrated circuits. These modules are mounted on a printed circuit board and designed for use in personal computers, workstations and servers.

In this patent application, a “resistor” can be any circuitry that performs the equivalent function of a resistor. “A component or an equivalent circuit with impedance that is substantially independent of frequency within the operation conditions of target application” meets the definition of the “resistor” in the present invention. One common example is to use transistors to serve the functions of a resistor as illustrated in FIGS. 7(d-g). A “capacitor” also can be any circuitry that performs the equivalent function of a capacitor. “A component or an equivalent circuit, where its conductance is proportional to frequencies, within operation conditions of target application” meets the definition of the “capacitor” in the present invention. One common example is to use transistors to serve the functions of capacitors as illustrated in FIGS. 7(c-f). Another common example is to use a diode to serve the functions of a capacitor. A “termination circuit” is defined as an electrical circuitry that is connected near (within 10 millimeters) the end of an electrical wire for the purpose of reducing the effects of reflections. An “RC termination circuit” defined in this patent application is a termination circuit that comprises at least one capacitor and one resistor connected in series as the impedance used to reduce reflection effects. Like any other circuit, a termination circuit may have unintentionally introduced parasitic capacitance. Such parasitic capacitance should not be considered as a capacitor of the present invention that is intentionally connected in series with termination resistor. A “voltage source” is an electrical circuit that provides stable voltage within operation conditions. Termination circuits are typically connected to voltage sources that are connected to bypass capacitors used to stabilize the voltage sources. Such bypass capacitors should not be considered as the capacitor used by termination circuits of the present invention.

The present invention provides power saving methods by replacing termination resistors used to support SSTL DRAM interfaces with RC termination circuits. Cost and space savings are achieved by integrated RC termination circuits, PCB level embedded components; chip package level embedded RC termination circuits, or IC level embedded RC termination circuits. The resulting termination circuits consume significantly less power than to prior art termination resistors while matching the characteristic impedance of electrical lines at high frequency. Similar methods and structures are also applicable for PCIe, SATA, or MIPI differential interfaces.

While specific embodiments of the invention have been illustrated and described herein, it is realized that other modifications and changes will occur to those skilled in the art. It is therefore to be understood that the appended claims are intended to cover all modifications and changes as fall within the true spirit and scope of the invention.

What is claimed is:

1. A method comprises a step of using RC termination circuits for reducing reflection effects of a plurality of dynamic random access memory (DRAM) interface signals on a DRAM dual in-line memory module (DIMM) comprising a plurality of DRAM integrate circuit (IC) chips operating at clock rate higher than 300 million cycles per second (MHZ).

2. The method in claim 1 further comprises a step of integrating a plurality of the RC termination circuits into one packaged component for using the packaged component in DRAM DIMM.

3. The method in claim 2 further comprises a step of packaging the RC termination circuits into a package having compatible footprint with a resistor array package according to a standard 0402 resistor array package.

4. The method in claim 2 further comprises a step of packaging the RC termination circuits and limiting resistors into one packaged component.

5. The method in claim 1 further comprises a step of using capacitor(s) embedded in a printed circuit board as a component in the RC termination circuit.

6. The method in claim 1 further comprises a step of using resistor(s) embedded in a printed circuit board as a component in the RC termination circuit.

7. The method in claim 1 further comprises a step of configuring the RC termination circuits and the DRAM IC chip into a same package.

8. The method in claim 1 further comprises a step of building and integrating the RC termination circuits as on-chip RC termination circuits of the DRAM IC chip.

9. The method in claim 1 wherein the step of using the RC termination circuits further comprises a step of building the RC termination circuits using screen printing technologies.

10. The method in claim 9 wherein the step of using the screen printing technologies further comprises a step of growing a thin film insulating layer on a structure printed by using a screen printing process.

11. The method in claim 1 wherein the step of using the RC termination circuits further comprises a step of using a transistor as an equivalent circuit to function as a resistor in the RC termination circuits.

12. The method in claim 1 wherein the step of using the RC termination circuits further comprises a step of using a transistor as an equivalent circuit to function as a capacitor in the RC termination circuits.

13. An electrical device operated at a clock rate higher than 300 million cycles per second (MHZ), comprising: a plurality of DRAM IC chips placed on a dual in-line memory module (DIMM) comprising a plurality of DRAM interface signal lines wherein the DRAM interface signal lines are connected to RC termination circuits.

14. The electrical device of claim 13 wherein: the RC termination circuits are integrated into one packaged component for placement on the DIMM.

15. The electrical device of claim 14 wherein: the packaged components containing the RC termination circuits having a compatible footprint with a resistor array packaged according to a standard 0402 resistor array package.

16. The electrical device of claim 14 wherein: the package component containing the RC termination circuits further containing limiting resistors in the packaged component.

17. The electric device of claim 13 wherein: the RC termination circuits comprise capacitor(s) embedded in a printed circuit board (PCB).

18. The electric device of claim 13 wherein: the RC termination circuits comprise resistor(s) embedded in a printed circuit board (PCB).

19. The electrical device of claim 13 wherein: the RC termination circuits are placed into a same package with the dynamic random access memory (DRAM) IC chip.

20. The electrical device of claim 13 wherein: the RC termination circuits are embedded into the DRAM IC chip as on-chip RC termination circuits.

21. The electrical device of claim 13 wherein: the RC termination circuits are manufactured using screen printing technologies.

22. The electrical device of claim 21 wherein: the capacitor of the RC termination circuits comprises a thin film insulating layer grown on the surface of screen-printed materials.

23. The electrical device of claim 13 wherein: the RC termination circuits comprise transistors configured to function as resistors.

24. The electrical device of claim 13 wherein: the RC termination circuits comprise transistors configured to function as capacitors.

25. A method for manufacturing capacitors comprises a step of growing a thin-film insulating layer on the surface of a screen-printed polycrystalline silicon layer.
